(19) United States
(12) Patent Application Publication
(10) Pub. No.: US 2025/0142716 A1
(43) Pub. Date: May 1, 2025

(54) PER LAYER ANTI-PAD STRUCTURE FOR BALL GRID ARRAY PRINTED CIRCUIT BOARD AND METHOD OF MANUFACTURE

(71) Applicant: Astera Labs, Inc., Santa Clara, CA (US)

(72) Inventors: Long YANG, Pleasanton, CA (US); Liang XUE, Los Altos, CA (US); Changyu SUN, Fremont, CA (US); Aleksandr OYSGELT, Palo Alto, CA (US)

(21) Appl. No.: 18/383,793

(22) Filed: Oct. 25, 2023

(51) Int. Cl. H05K 1/02; H01L 21/48; H01L 23/498; H05K 3/46

(52) U.S. Cl. CPC H05K 1/0251; H01L 21/4857; H01L 23/49822; H01L 23/49838; H05K 3/4644; H05K 2201/0939; H05K 2201/09481

(57) ABSTRACT

An electronic system having a mounting substrate with a plurality of layers. The mounting substrate includes a plurality of layers having pad structures each configured with a pad within an anti-pad opening. The pad structures are connected with via. The pad structures are configured to reduce the impedance of the via by altering the shape, size, and position of the pads and the anti-pad openings. The pads of the pad structures are configured as functional and non-functional pads based on the impedance targets for the vias.

### TECHNICAL FIELD

Embodiments relate generally to electrical structures for improving performance in electronic circuit packages with ball grid array structures and more specifically, to electrical printed circuit boards with per layer anti-pad structures to improve performance and reducing inductance and methods of manufacture.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

The development of electronic circuitry and products has been influenced by the physical and electrical properties of the materials and structures used to form the electronic components and electric circuitry.

Electronic components must be electrically connected to other electronic components and system for proper operation. Electronic components can be mounted on multilayer circuit boards and electrically coupled with power distribution networks having vertical vias, signal traces, power traces, and ground traces. The size, shape, power levels, and electrical parameters of the electronic components can have an impact on the operational performance.

The electrical properties of the electronic components and power distribution components can influence the electrical operating properties of the circuit and negatively result in instability, oscillation effects, signal leakage, reflection, frequency change, and other unintended effects. Reducing the effect of such electrical configurations can reduce unwanted effect and increase the overall efficiency of the circuit operation.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 depicts an example embodiment of an electronic system,

FIG. 2 depicts an example of the mounting substrate in an embodiment of the electronic system,

FIG. 3 depicts an example of a via pad stack 302 in an embodiment of the electronic system,

FIG. 4A depicts an example embodiment of the via pad stack,

FIG. 4B depicts an example embodiment of the via pad stack with non-functional pads,

FIG. 5A depicts an example embodiment of one of the vias with a rectangular anti-pad and a circular via pad,

FIG. 5B depicts an example embodiment of one of the vias with an oval anti-pad and a circular via pad,

FIG. 5C depicts an example embodiment of one of the vias with a square anti-pad and a circular via pad,

FIG. 5D depicts an example embodiment of one of the vias with a dumbbell anti-

pad and a circular via pad,

FIG. 5E depicts an example embodiment of one of the vias with a circular anti-

pad and a circular via pad,

FIG. 6A depicts an example of the mounting substrate formed with a uniform material,

FIG. 6B depicts an example of the mounting substrate formed with a hybrid material,

FIG. 7 depicts an example of a terminal time domain reflectivity (TDR) impedance graph for an embodiment of the electronic system,

FIG. 8 depicts an example of a terminal time domain reflectivity impedance graph for another embodiment of the electronic system,

FIG. 9 depicts an example of a terminal time domain reflectivity impedance graph for other embodiments of the electronic system, and

FIG. 10 depicts an example of a manufacturing process flow for the electronic system in an embodiment.

### DETAILED DESCRIPTION

In the following detailed description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

Embodiments are described herein according to the following outline:
1.0 Overview
2.0. System Overview
3.0 Performance Analysis
4.0 Functional Overview
5.0. Example Embodiments
6.0. Extensions and Alternatives

### 1.0. Overview

Approaches, techniques, and mechanisms are disclosed for manufacturing and use of the electronic systems discussed herein including electronic systems with multi-layer components and substrates. The electronic systems can improve performance and reduce electrical operating factors between conductive elements by creating directional current flow structures to compensate for inductance and capacitance factors between and around elements in the multi-layer substrates. By reducing loop inductance between various conductive elements in both electronic packages and the underlying printed circuit boards, operating frequencies can be increased.

According to an embodiment, the system can include two or more pad structures connected by a via where the pad structures are configured to reduce the via impedance. The pad structures can include different configurations of a pad within an anti-pad opening.

According to an embodiment, the system can include two or more pad structures having different configurations of the pad shape, the pad area, the anti-pad shape, and the anti-pad size.

According to an embodiment, the system can include two or more pad structures connected by a via where the pad structures are configured to reduce the via impedance by varying the distance between the end of the via and the placement of the pad structure.

According to another embodiment, the electrical system can include attaching an electronic component to the mounting substrate. The mounting substrate can include the electronic components attached to a via coupled to one or more of the pad structures to reduce via impedance and improve performance.

In other aspects, the inventive subject matter encompasses electronic systems configured to carry out the foregoing techniques.

### 2.0. System Overview

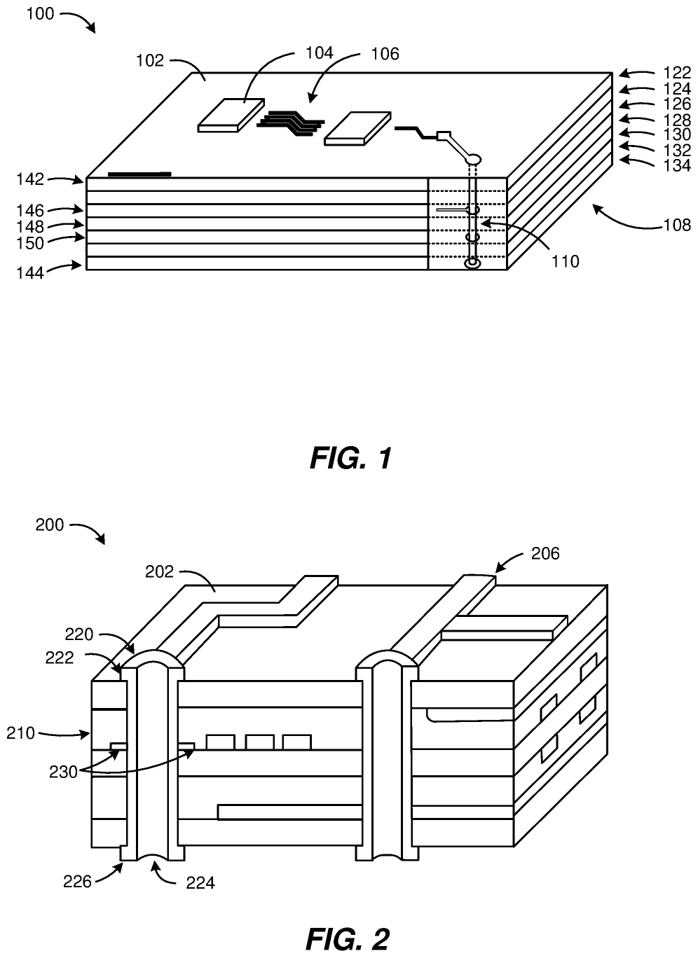

FIG. 1 illustrates an example embodiment of an electronic system 100. The electronic system 100 can have electronic components 104 attached to a mounting substrate 102. The mounting substrate 102 can couple the electronic components 104 to other ones of the electronic components 104 and to other portions of the system 100.

The electronic system 100 can be a system or submodule of a system. For example, the electronic system 100 can be an electronic package, a printed circuit board, a motherboard, a daughter board, a standalone system, or other similar systems and devices.

The electronic system 100 can include one or more of the electronic components 104 attached to the mounting substrate 102. The mounting substrate 102 is a multilayer structure for coupling electronic components 104 to other electronic components 104 and to the rest of the electronic system 100. The layers of the mounting substrate 102 can have a variety of configurations. For example, the layers can be a combination of insulating materials and conductive traces transferring signals or power. The electronic components 104 can be coupled to other components with signal traces 106. The signal traces 106 are conductive paths for transferring signals and power. In another embodiment, the mounting substrate 102 can be a printed circuit board 108 (PCB 108), electronic package, or other similar elements.

The mounting substrate 102 can have a variety of types of different layers. In some embodiments, the mounting substrate 102 can have layers including signal trace layers, power layers, ground plane layers, insulation layers, electromagnetic shielding layers, external connection layers, and/or other similar layers.

The electronic components 104 are the elements used to provide the functionality of the electronic system 100. The electronic components 104 can be active or passive components. For example, the electronic components 104 can be active components such as integrated circuits, processors, field programmable gate arrays, transistors, ball grid array components, or other similar active components. The electronic components 104 can be passive components such as resistors, capacitors, inductors, connectors, interfaces, contact pads, or other similar passive components.

The mounting substrate 102 can include a plurality of substrate layers 110 formed from insulating and conductive materials. For example, the mounting substrate 102 can include a conductive top portion formed on an insulating dielectric portion of the substrate layer 110.

In an illustrative embodiment, the mounting substrate 102 can include a first layer 122, a second layer 124, a third layer 126, a fourth layer 128, a fifth layer 130, a sixth layer 132, and a seventh layer 134. In other embodiments, the mounting substrate 102 can be configured with a different number of layers.

The mounting substrate 102 can have a variety of configurations. The mounting substrate 102 can include a top layer 142 on a top side of the mounting substrate 102, such as the first layer 122. A bottom layer 144 can be on a bottom side of the mounting substrate 102, such as the seventh layer 134. The mounting substrate 102 can include one or more inner layers 146 between the top side and the bottom side. The mounting substrate 102 can include a ground layer 148 and a power layer 150.

The substrate layers 102 can be configured in a variety of ways. In some embodiments, the substrate layers 102 can have a conductive layer, such as a copper layer, formed directly on a dielectric layer, such as a fiberglass or prepreg layer. The copper layer can be configured to form conductive traces for conducting signals and power to the electronic components.

The substrate layers 102 can be coupled vertically with vias 110. The vias 110 are vertical conductors that can conduct signals between different layers of the mounting substrate 102. The vias 110 can be through board vias, internal vias, blind vias, stacked vias, staggered vias, buried vias, or other similar types of vertical interconnects.

In some embodiments, the via 110 can form a vertical interconnection between two layers that can include two or more horizontally offset vertical segments electrically coupled together on an intermediate layer, such as two individual via segments offset from one another but both electrically coupled at an intermediate layer between the two via segments. In an illustrative example, the vertical interconnect can include a top via segment offset from a middle via segment which is coupled to a bottom via segment. Each of the via segments can be one of the vias 110 such as an internal via, blind via, stacked via, staggered via, buried via, or other similar types of vertical interconnect.

The electronic components 104 can be attached to the printed circuit board 108 in a variety of ways. The electronic components 104 and the other components can be electrically coupled to the traces of the printed circuit board 108 by mounting, soldering, pressure connected, adhesive attachment, or other similar techniques.

In other embodiments, the electronic components 104, such as a ball grid array package, can be attached to the mounting substrate 102. The connection to the printed circuit board 108 can have a variety of configurations. The electronic components 104 can be attached directly to the printed circuit board 108, indirectly mounted in a socket, connected to another component, stacked, linked via a network connection, attached through a connector, or other techniques.

The configuration of the circuitry of the electronic system 100 can produce electrical effects that can impact the performance of the electronic system 100. Inductance, resistance, reactance, and capacitance are basic elemental properties of all electrical systems.

FIG. 2 illustrates an example of the mounting substrate 202 in an embodiment of the electronic system 200. The mounting substrate 202 can include a plurality of traces 206 and vias 220.

The traces 206 are conductive elements for transferring power and signals between the electrical components 104 and other system components. The substrate traces 206 can be formed in a variety of ways. For example, the traces 206 can be formed by applying a mask and photoetching the conductive portion of one of the layers.

The mounting substrate 202 can include vias 220 providing vertical interconnection between two or more layers. The vias 220 can extend through one or more of the substrate layers 210.

The vias 220 can be electrically coupled to a via pad 222 on one of the substrate layers 210. The via pad 222 can be located at the top side or bottom side of one of the vias 220 to provide connectivity to other elements. The via pad 222 is a conductive element for connecting to the vias 220.

The mounting substrate 202 can include a variety of pads that are conductive elements. The pads can include via pads, interface pads, contact pads, mounting pads, stacking pads, and/or other similar types. The term pad can be used interchangeably for the different types of pads.

The vias 220 can be formed in a variety of ways. In some embodiments, the vias 220 can be formed by drilling a via hole 226 and plating the inside of the via hole with a conductive material to form via walls 224.

In some embodiments, the vias 220 can be electrically coupled to one or more internal pads 230 embedded within substrate layers of the mounting substrate 202. The internal pads 230 are horizontal interconnect structures that can be electrically coupled to one or more of the substrate traces 206.

In other embodiments, the vias 220 can be configured to operate like transmission lines, depending on the frequency of the signals being conducted.

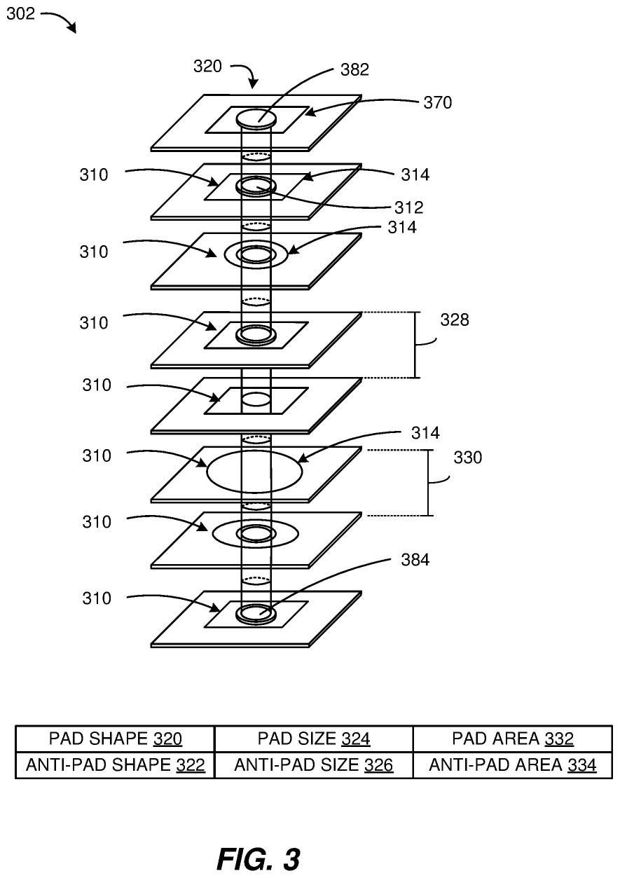

FIG. 3 illustrates an example of a via pad stack 302 in an embodiment of the electronic system 100. The via 320 can provide electrical connectivity between different layers of the mounting substrate 102.

In some embodiments, the top layer of the via pad stack 302 can include a top pad 382. The top pad 382 is a conductive element that can be coupled to the signal traces 106 on the top layer 142. The top pad 382 is electrically coupled to the via 320.

The via pad stack 302 can include a pad structure 310 on a layer between the top pad 382 and the bottom pad 384. The pad structure 310 can be on a single layer of the mounting substrate 102. The pad structure 310 is a conductive element for interacting with the via 320.

In some embodiments, the pad structure 310 can be in direct contact with the via 320. The pad structure 310 can be indirectly coupled to the via 320, such as having a conductive element around the via 310, but not in direct contact with the via 310.

The pad structure 310 can have a variety of configurations. The pad structure 310 can include a pad 312 formed within the opening of an anti-pad 314. The pad 312 is a conductive element on one of the layers of the mounting substrate 102. The pad 312 can be electrically coupled to the signal traces on the layer of the mounting substrate 102. The pad 312 has a pad shape 320, a pad size 324, and a pad area 332. The pad shape 320 can be configured as a circle, square, rectangle, oval, or other shape types. The pad size 324 can be a complex value based on the pad shape 320. For example, the pad size 324 can be a length and width, a radius, a diameter, major and minor axes, or other dimensions. The pad area 332 is the area of the pad 312 calculated based on the pad size 324.

The pad structure 310 can be separated from another pad structure 310 by an offset distance 328, such as a first offset distance. The offset distance 328 can represent the distance between the pad structure 310 and another pad structure 310 on different layers. The offset distance 328 can represent the distance between two pad structures 310 on adjacent layers or more than one layer away. For example, the offset distance 328, such as a second offset distance, can represent the distance between two pad structures 310 separated by two layers. The offset distance 328 can be configured to reduce the via impedance at different locations on the via 320. For example, the pad structures 310 can be configured to have the first offset distance at the equivalent of two layers apart with a different pad structure between the two pad structures.

In some embodiments, the layers can have a variety of layer heights 330. For some high-speed PBCs, the layer height 330 can vary from 3 mils to 5 mils. The pad structures 310 can be separated by multiples of the layer height 330. In other embodiments, the layer height 330 can be based on the impedance, thickness requirements, routing factors, and other similar factors. The offset distance 328 can be fine-tuned based on the layer height 330 and the number of layers between the pad structures 310.

In some embodiments, the offset distance 328 can include one or more other pad structures 310 between the two pad structures 310 that are used to determine the offset distance 328. In other embodiments, such vias 320 can be configured to include pad structures, functional pads, non-functional pads, layers with no pad structures, or other similar configurations.

The anti-pad 314 is an opening in the conductive material of one of the layers of the mounting substrate 102. The anti-pad 314 forms a non-conductive area around the pad 312. The anti-pad 314 can have an anti-pad opening 370 devoid of conductive material and where the pad 312 can be located.

The anti-pad 314 has an anti-pad shape 322, an anti-pad size 326, and an anti-pad area 334. The anti-pad shape 322 can be configured as a circle, square, rectangle, oval, dumbbell, a combination thereof. The anti-pad size 326 can have a complex value based on the anti-pad shape 322 and include multiple individual values. For example, the anti-pad size 326 can be a length and width, a radius, a diameter, major and minor axes, or other dimensions. The anti-pad area 334 is the area of the anti-pad 314 calculated based on the anti-pad size 326.

In some embodiments, the pad structure 310 can include the pad 312 configured as a circular pad around the via 320 and the anti-pad 314 configured as a rectangle. In other embodiments, the two or more of the pads 312 can be located within a single one of the anti-pads 314.

In an embodiment, the pad structure 310 can have the pad 312 with a circular shape surrounded by the anti-pad 314 having an anti-pad shape 322 of circular or oval shape. The pad 312 can be centered within the anti-pad 314 or be offset from the center of the anti-pad 314.

In another embodiment, the pad structure 310 can include only the anti-pad 314. In this configuration, the via 320 can be formed through the opening of the anti-pad 314 without making direct electrical contact with other conductive elements on the layer.

In yet another embodiment, the pad structure 310 can include two of the circular pads within the anti-pad 314 and where the anti-pad shape 322 is configured to be a dumbbell shape. The dumbbell shape can be configured as two circular shapes intersecting and directly connected together. In other configurations, the dumbbell shape can be configured as two circular shapes separated by an offset with an extension member connecting the two circular shapes.

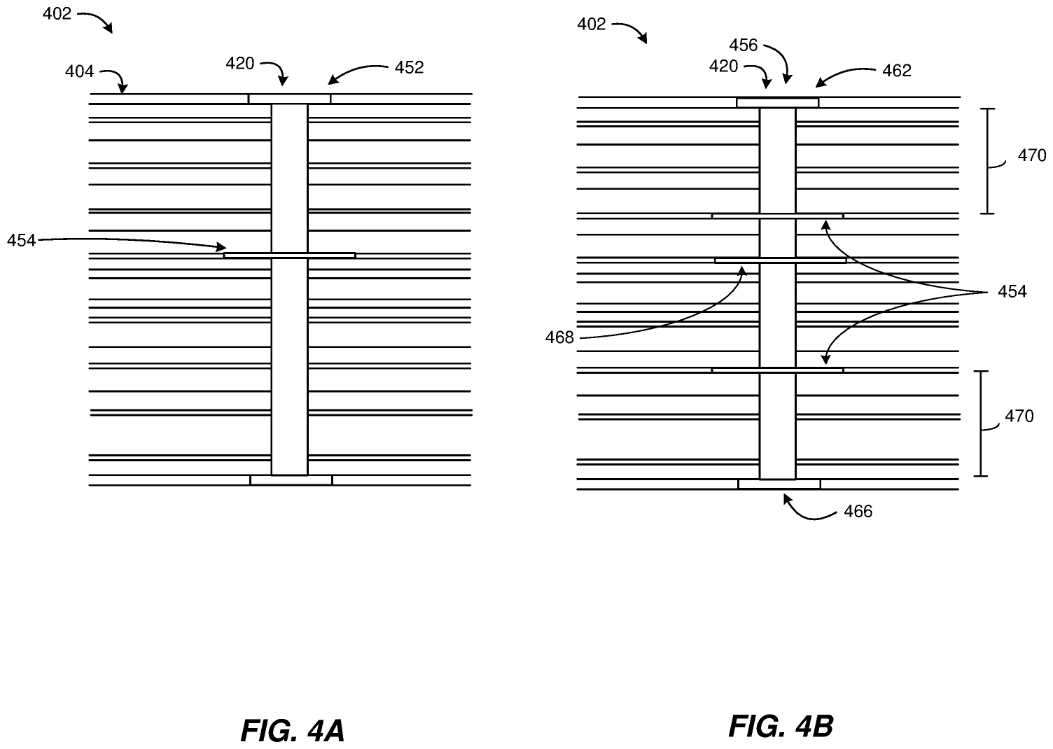

FIGS. 4A and 4B illustrate examples of via pad stacks 402 in an embodiment of the electronic system 100. The via 420 can provide electrical connectivity between different layers of the mounting substrate 404.

FIG. 4A illustrates an example embodiment of the via pad stack 402. The via pad stack 402 is the set of elements forming the vertical interconnect of the via 420. The via pad stack 402 can include the vertical conductive structure that can be coupled to pad structures 310 at different layers of the mounting substrate 404. The pads can be coupled to traces to conduct signals to different layers of the mounting substrate 404.

The via pad stack 402 can include functional pads 452 and non-functional pads 454. The functional pads 452 can be coupled to some of the traces at different layers of the mounting substrate 404. The non-functional pads 454 are coupled to one of the vias 420 and not coupled to the traces.

FIG. 4B illustrates an example embodiment of the via pad stack 402 with non-functional pads 454. The implementation of adding the non-functional pads 454 varies depending on several factors, including the PCB material, structure, a uniform material stackup, a hybrid material stackup, or other similar factors. These factors play an important role in determining the specific approach used for incorporating the non-functional pads 454.

In some embodiments, the via 420 can be configured as a through hole via 456. The through hole via 456 can extended from the top layer to the bottom layer.

The through-hole via 456 can have a variety of configurations. For example, the through hole via 456 can include at least one of the non-functional pads 454. The non-functional pad 454 can be configured with a pad offset 470, such as a first pad offset, located 20 mil away from the top signal pad 462 and another non-functional pad 454 configured with the pad offset 470, such as a second pad offset, located 20 mil away from the bottom signal pad 464. If the spacing between these two non-functional pads exceeds 20 mil, a third non-functional pad can be added in the middle.

In another embodiment, the via can be configured as a backdrilled via 466. The backdrilled via 466 can include one of the non-functional pads 454 located 20 mil away from the top signal pad 462 and another one of the non-functional pads 454 located 30 mil away from the bottom signal pad 464. If the spacing between these two non-functional pads 454 exceeds 20 mil, a third non-functional pad 468 can be added between the other two non-functional pads 454.

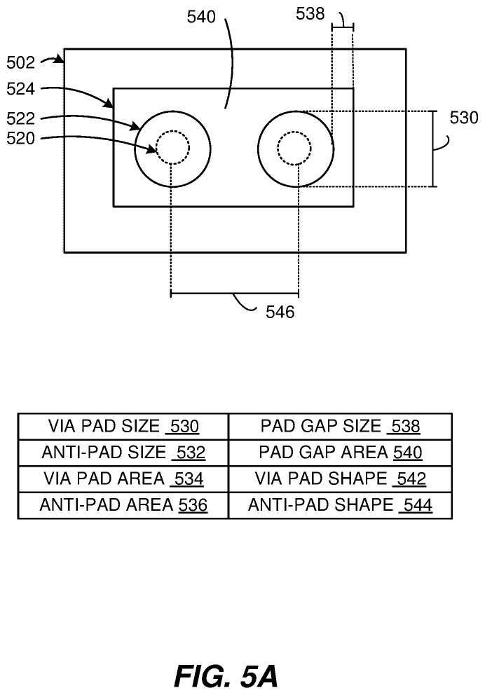

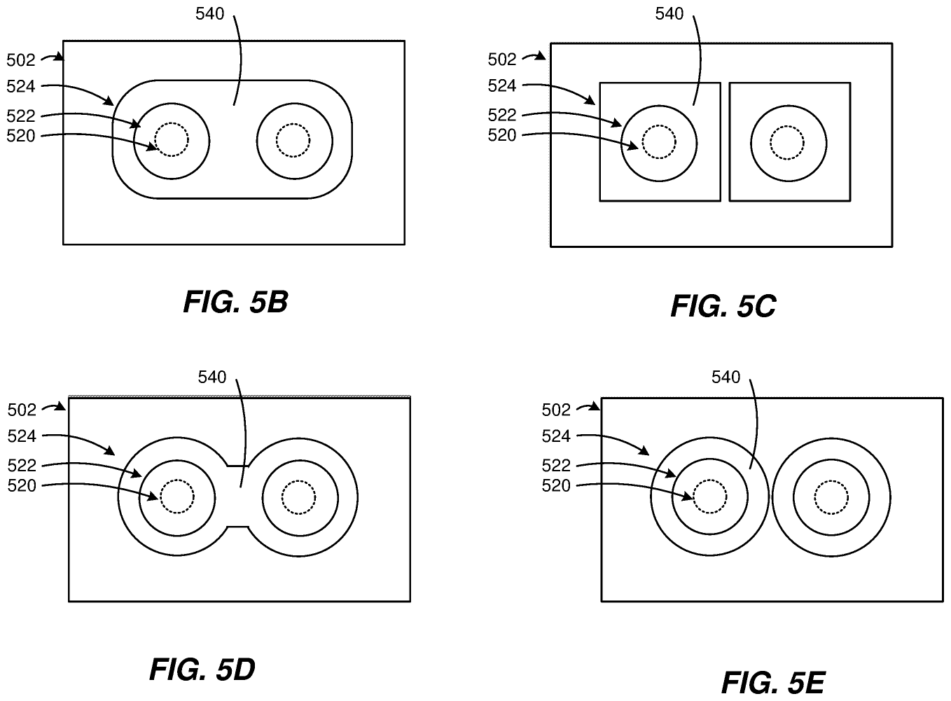

FIGS. 5A, 5B, 5C, 5D, 5E, and 5F illustrate examples of vias 520 in embodiments of the electronic system 100. The vias 520 can provide electrical connectivity between different layers of the mounting substrate 502.

FIG. 5A illustrates an example embodiment of one of the vias 520 with a rectangular anti-pad 524 and a circular via pad 522. A pad structure 502 can include the via 520 can be coupled to the circular via pad 522.

The anti-pad 524 is an opening where the conductive material has been removed. The anti-pad 524 can be a rectangular anti-pad. The rectangular anti-pad 524 can have an anti-pad size 532. The anti-pad size 532 can be a complex value based on an anti-pad shape 544. The anti-pad size 532 can include values such as a length and a width, radius, diameter, major axis, minor axis, or other shape-based dimensions that can be used to determine an anti-pad area 534. The anti-pad 524 can have an anti-pad opening 540.

The circular via pad 522 is a conductive pad having a circular shape. The circular via pad 522 can be electrically coupled to the via 520. The circular via pad 522 can have a via pad size 530 and a via pad area 534. The via-pad size 530 can be a complex value based on a via pad shape 542. The via pad size 530 can include values such as a length and a width, radius, diameter, major axis, minor axis, or other shape-based dimensions that can be used to determine the via pad area 534.

The circular via pad 522 can have a variety of parameters. The circular via pad 522 can include the via pad size 520, such as a diameter. The circular via pad 522 can have a pad gap area 540. The pad gap area 540 is the difference the anti-pad area 536 and the via pad area 534. The distance between a side of the anti-pad 524 and the via pad 522 can be a pad gap size 538. The relative size of the via pad size 530 and the anti-pad size 532 can be configured to achieve the desired impedance performance.

In some embodiments, the via pad area 534 can be approximately the same size as the pad gap area 540. In other embodiments, the via pad area 534 can be smaller than the pad gap area 540. The relative sizes of the via pad area 534 and the pad gap area 540 can be configured based on the desired impedance along the via 520. For example, the impedance along the via 520 can be manipulated by using two identically configured pad structures 502 on adjacent layers, two identically configured pad structures 502 separated by two or more layers, two differently configured pad structures 502 on adjacent layers, two differently configured pad structures 502 separated by two or more layers, or a combination thereof. In other examples, the via 520 can be coupled to different numbers of the pad structures 502 along the via 520. The pad structures 502 can be of similar or different configurations regarding shape, size, and area.

In some embodiments, the via 520 can be coupled to two adjacent pad structures 502 of similar or dissimilar configurations. The similar configurations can vary from one another in one or more parameters including size, shape, area, or a combination thereof. In other embodiments, the via 520 can be coupled to two or more of the pad structures 502 separated by different numbers of layers.

In yet other embodiments, two of the vias 520 within one of the anti-pads 524 can be separated from one another by a via separation distance 546 representing the horizontal distance between the vias 520. The pad structure 502 can include one or more of the vias 520 passing through one of the anti-pads 524.

FIG. 5B illustrates an example embodiment of one of the vias 520 with an oval anti-pad 524 and a circular via pad 522. The via 520 can be coupled to the circular via pad 522.

The anti-pad 524 can have an oval anti-pad shape 544. The anti-pad 524 can have the anti-pad size 532. The anti-pad size 532 can be a complex value based on an anti-pad shape 544. The anti-pad size 532 can include values such as a length and a width, radius, diameter, major axis, minor axis, or other shape-based dimensions that can be used to determine an anti-pad area 534.

The circular via pad 522 can have the via pad size 530 and the via pad area 534. The via-pad size 530 can be a complex value based on the via pad shape 542.

The circular via pad 522 can have a variety of parameters. The circular via pad 522 can include the via pad size 520, such as a diameter. The circular via pad 522 can have the pad gap area 540. The pad gap area 540 can be the difference of the anti-pad area 536 and the via pad area 534.

The anti-pad 524 with an oval anti-pad shape 544 can be configured to be closer the circular via pad 522. This can result in a smaller value for the pad gap area 540. This can impact the impedance of this configuration.

FIG. 5C illustrates an example embodiment of one of the vias 520 with a square anti-pad 524 and a circular via pad 522. The via 520 can be coupled to the circular via pad 522. In some embodiments, two of the vias 520 can each have the square anti-pad 524 and be positioned adjacent to one another.

The anti-pad 524 can have a square anti-pad shape 544. The anti-pad 524 can have an anti-pad size 532. The anti-pad size 532 can be a complex value based on the anti-pad shape 544. The anti-pad size 532 can include values for a length and a width that can be used to determine an anti-pad area 534.

The circular via pad 522 can have the via pad size 530 and the via pad area 534. The via-pad size 530 can be a complex value based on the via pad shape 542.

The circular via pad 522 can have a variety of parameters. The circular via pad 522 can include the via pad size 520, such as a diameter. The circular via pad 522 can have the pad gap area 540. The pad gap area 540 can be the difference of the anti-pad area 536 and the via pad area 534.

The anti-pad 524 with a square anti-pad shape 544 can be configured to be closer to the circular via pad 522. This can result in a smaller value for the pad gap area 540. This can impact the impedance of this configuration.

FIG. 5D illustrates an example embodiment of one of the vias 520 with a dumbbell anti-pad shape 524 and circular via pads 522. The via 520 can be coupled to the circular via pad 522. In some embodiments, two of the vias 520 can each be within the dumbbell anti-pad 524 and be positioned adjacent to one another.

The anti-pad 524 can be a square anti-pad with a dumbbell anti-pad shape 544. The dumbbell shape can be formed by coupling two circular openings together with a rectangular opening. The dumbbell anti-pad 524 can have the anti-pad size 532. The anti-pad size 532 can be a complex value based on the anti-pad shape 544. The anti-pad size 532 can include values for a length and a width that can be used to determine an anti-pad area 534.

The circular via pad 522 can have the via pad size 530 and the via pad area 534. The via-pad size 530 can be a complex value based on the via pad shape 542.

The circular via pad 522 can have a variety of parameters. The circular via pad 522 can include the via pad size 520, such as a diameter. The circular via pad 522 can have the pad gap area 540. The pad gap area 540 can be the difference of the anti-pad area 536 and the via pad area 534.

The anti-pad 524 with a square anti-pad shape 544 can be configured to be closer to the circular via pad 522. This can result in a smaller value for the pad gap area 540. This can impact the impedance of this configuration.

FIG. 5E illustrates an example embodiment of one of the vias 520 with a circular anti-pad 524 and a circular via pad 522. The via 520 can be coupled to the circular via pad 522. In some embodiments, two of the vias 520 can each have the circular anti-pad 524 and be positioned adjacent to one another.

The anti-pad 524 can have a circular anti-pad shape 544. The anti-pad 524 can have an anti-pad size 532. The anti-pad size 532 can be a complex value based on the anti-pad shape 544. The anti-pad size 532 can include values for a diameter that can be used to determine the anti-pad area 534.

The circular via pad 522 can have the via pad size 530 and the via pad area 534. The via-pad size 530 can be a complex value based on the via pad shape 542.

The circular via pad 522 can have a variety of parameters. The circular via pad 522 can include the via pad size 520, such as a diameter. The circular via pad 522 can have the pad gap area 540. The pad gap area 540 can be the difference of the anti-pad area 536 and the via pad area 534.

The anti-pad 524 with a square anti-pad shape 544 can be configured to be closer to the circular via pad 522. This can result in a smaller value for the pad gap area 540. This can impact the impedance of this configuration.

In some embodiments, the configuration of the pad structures positioned along one of the vias can be configured to improve the impedance profile along the via 520. For example, the via 520 can be configured to have two pad structures 502 separated on adjacent layers, separated by multiple layers, or a combination thereof.

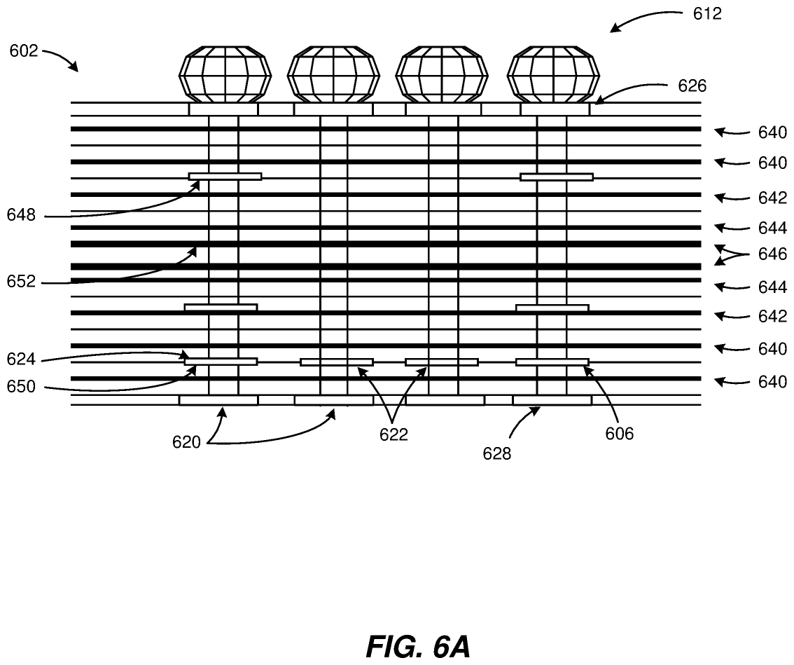

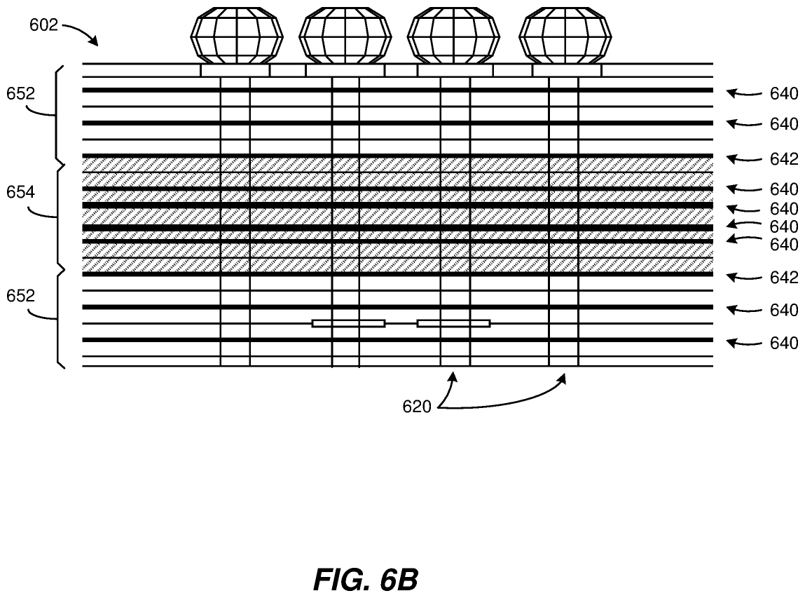

FIGS. 6A and 6B, illustrate examples of shaped anti-pads 620 in embodiments of the electronic system 100. The vias 620 provide electrical connectivity between different layers of the mounting substrate 602. Some of the layers can include the different embodiments of the shaped anti-pad 620.

FIG. 6A illustrates an example of the mounting substrate 602 formed with a uniform material. The vias 620 can transfer signals between top signal pads 626 and bottom signal pads 628 as well as between other intermediate layers. The top signal pads 626 can be coupled to a solder ball 612. The vias 620 can act like a transmission line. At each layer, the vias 620 can be configured with a pad structure 606 to modify the impedance of the vias 620. The vias 620 can be configured with the pad structure 606 being a functional pad 648, a non-functional pad 650, or no pad 652. The pad structure 606 can have a via pad 622 combined to an anti-pad 624.

In an illustrative embodiment, the mounting substrate 602 can include multiple layers where each layer has a pad structure 606 to configure the impedance of the via 620. The via 620 can be configured with two rectangular anti-pads 640, an oval anti-pad 642, a dumbbell anti-pad 644, two circular anti-pads 646, another one of the dumbbell anti-pads 644, another oval anti-pad 642, and two rectangular anti-pads 640. The via 620 can be configured by using the pad structures 606 to modify the impedance of the via 620. The mounting substrate 602 can be implemented using uniform material for the printed circuit board stackup.

FIG. 6B illustrates an example of the mounting substrate 602 formed with a hybrid material. The hybrid material can include prepreg, core, or other similar materials for different layers.

The mounting substrate 602 can include the via 620 configured with two rectangular anti-pads 640, an oval anti-pad 642, four of the rectangular anti-pads 640, another oval anti-pad 642, and two rectangular anti-pads 640. In some embodiments, the layers between the two oval anti-pads 642 can be formed from a low-speed material layer 654 that is different from higher speed dielectric material layers 652 on the upper and lower layers.

### 3.0. Performance Analysis

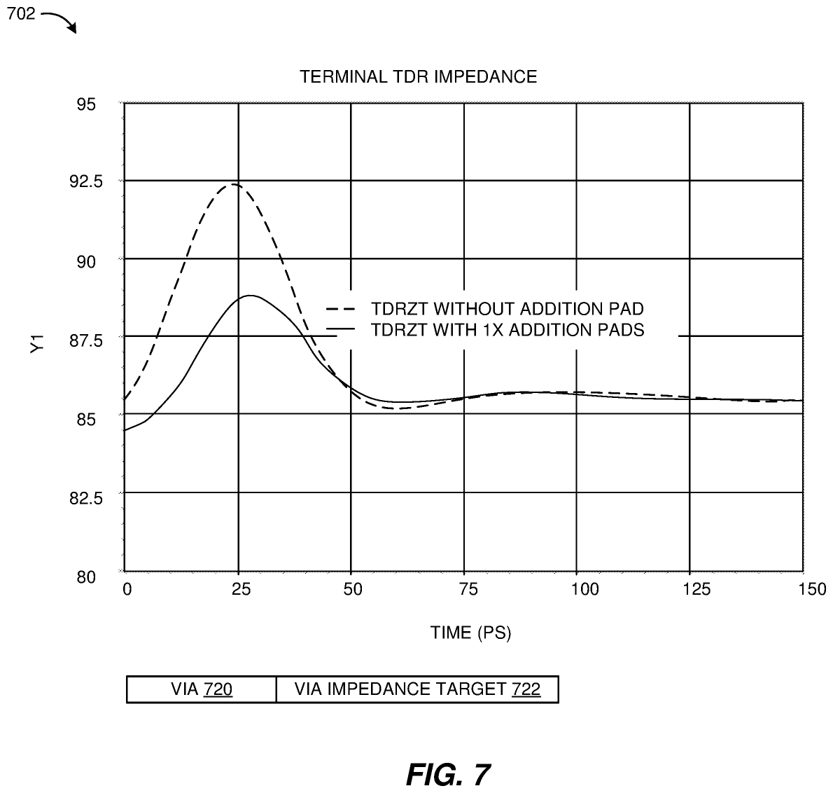

FIG. 7 illustrates an example of a terminal time domain reflectivity (TDR) impedance graph 702 for an embodiment of the electronic system 100. The terminal TDR impedance graph 702 show the reflection along one of the vias 720.

In some embodiments, using ultra-low-loss PCB dielectric materials, such as core and prepreg, can achieve a via impedance target 722 by removing all non-functional pads 454 is often limited in the BGA region due to physical constraints. The use of additional non-functional pads 454 can help reduce impedance of the via 720 to achieve the target value. The via impedance target 722 is the desired impedance levels for the via 420. The via impedance target 722 can be represented by a single average value, a set of impedance values over a range of time, a set of impedance values over a range of distance from one end of the via, or a combination thereof.

The terminal TDR impedance graph 702 show the impedance reflection with no additional pads and with one additional non-functional pads 454. The addition of the additional pad reduces the impedance approximately 5% as shown at the 25 picosecond (ps) mark. In some embodiments, the via impedance can be reduced by the addition of one of the pad at a location corresponding to the reflection time of a portion of the TDR impedance graph, such as a peak in the impedance. In some embodiments, the location of a peak or other point in the TDR impedance graph can be an approximate representation of the offset distance.

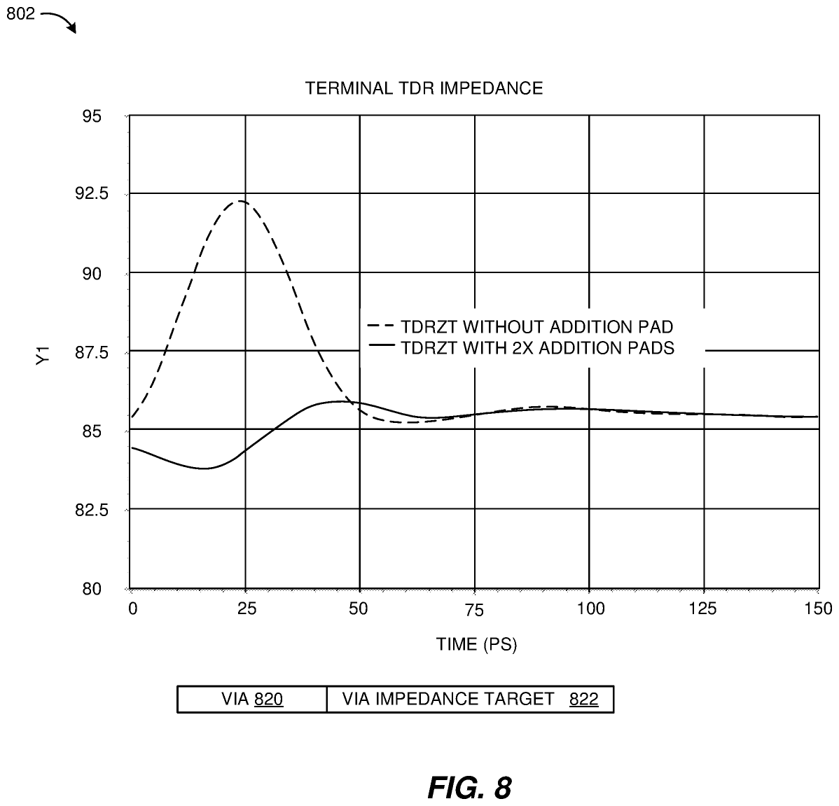

FIG. 8 illustrates an example of a terminal time domain reflectivity impedance graph 802 for another embodiment of the electronic system 100. The terminal TDR impedance graph 802 shows the reflection along a via 820.

In some embodiments, using ultra-low-loss PCB dielectric materials, such as core and prepreg, can achieve a via impedance target 822 by removing all non-functional pads 454 is often limited in the BGA region due to physical constraints. The use of additional non-functional pads 454 can help reduce impedance of the via 820 to achieve the target value. The via impedance target 822 is the desired impedance levels for the via 820.

The terminal TDR impedance graph 802 shows the impedance reflection with no additional pads and with two additional non-functional pads 454. The addition of the additional two pads reduces the impedance by approximately 10% as shown at the 25 picosecond (ps) mark. The impedance reduction shows that the addition of the non-functional pads 454 can improve performance of the system. In some embodiments, the via impedance can be reduced by the addition of one of the nonfunctional pads at a location corresponding to the reflection time of a portion of the TDR impedance graph, such as a peak in the impedance. In other embodiments, the location of a peak or other point in the TDR impedance graph can be an approximate representation of the offset distance.

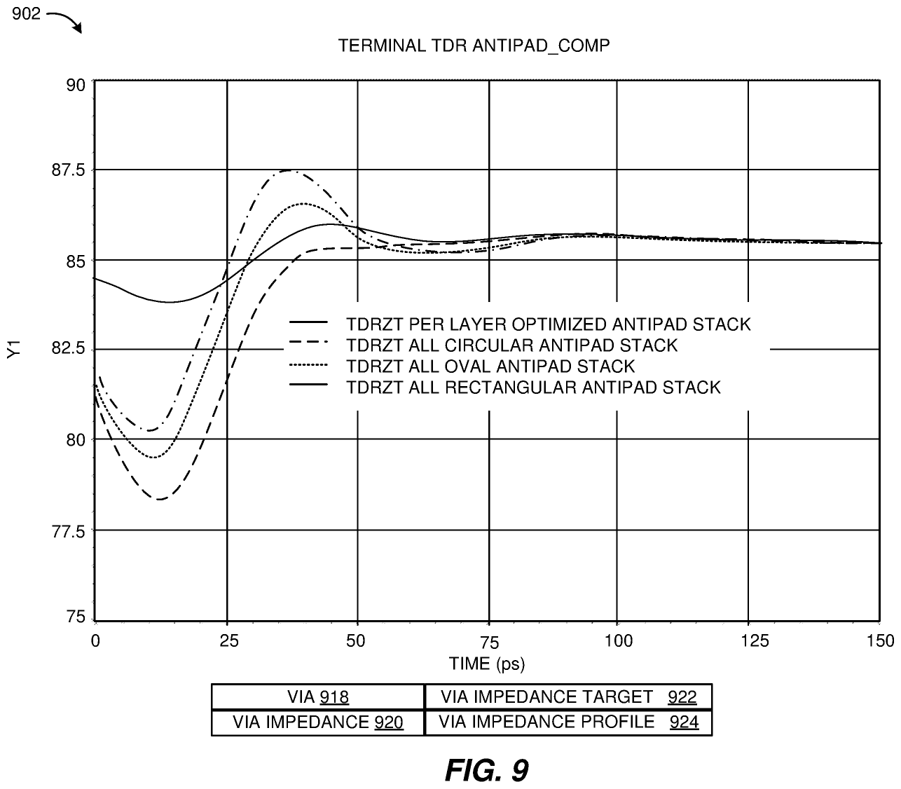

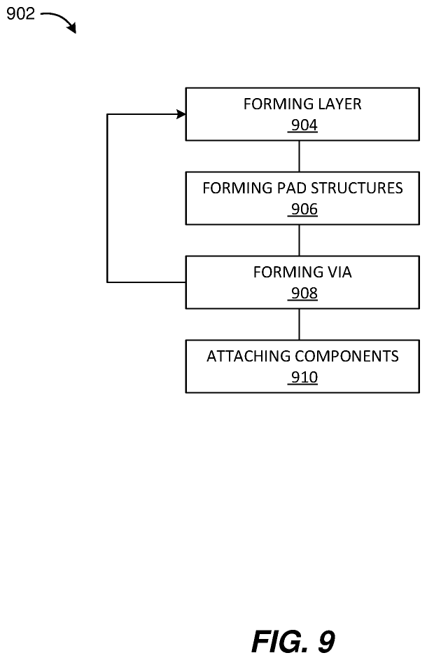

FIG. 9 illustrates an example of a terminal time domain reflectivity (TDR) impedance graph 902 for other embodiments of the electronic system 100. The terminal TDR impedance graph 902 shows the reflection along one of the vias 920 with some non-functional pads 454 having different anti-pad shape characteristics.

The impedance of a via 918 can exhibit variations based on its location along the via structure and the shape of both the anti-pad 524 and the pad 522. In some embodiments, a uniform shape can be used across all of the layers, but this approach can lead to deviations in impedance from the desired target impedance at different locations along the via 918. These deviations can manifest as impedance values that are either higher or lower than the intended target impedance. Thus, these deviations can result in increased return loss and diminish overall system margin in end-to-end high-speed signaling. The use of additional non-functional pads 454 can help reduce impedance of the via 918 to achieve the target value. The selection of the pad location can be based on the initial measurement of the TDR impedance graph 902.

The terminal TDR impedance graph 902 shows the impedance reflection with no additional pads and with two additional non-functional pads 454. The addition of the additional two pads reduces the impedance by approximately 10% as shown at the 25 picosecond (ps) mark. The impedance reduction shows that the addition of the non-functional pads 454 can improve performance of the system. In some embodiments, the via impedance 920 can be reduced by the addition of one of the pads having a particular shape characteristic at a location corresponding to the reflection time of a portion of the TDR impedance graph, such as a portion representing a peak in the impedance. In some embodiments, the location of a peak or other point in the TDR impedance graph can be an approximate representation of the offset distance.

In other embodiments, the mounting substrate 102 can be formed using hybrid materials to for the stack structure. The hybrid materials can allow the use of high performance and lower performance materials as needed. This can allow for fine tuning the PCB fabrication in high-speed signaling applications beyond 50 Gb/s by matching the properties of the materials with the needed performance properties. These stackups employ high-end materials in layers with ultra high-speed signal routings, while using low-end materials in other areas, such as between Power and GND layers and low-speed signal routing layers.

In some configurations there can be significant variation in the via impedance 920 due to the different dielectric constants of the high-end and low-end materials. The per-layer pad stack and anti-pad stack approach can be configured to modify a via impedance profile 924 and compensate for the differences induced by the change of dielectric materials. The impedance profile 924 can be the desired impedance measured at each of the levels of the via. The impedance profile 924 can be configured to reduce the overall via impedance and can be influenced by the trace and component layout of each of the layers. By configuring the pad 522 and anti-pad 524 of the pad structure 310, this enables the customization of via impedances 920 in the different regions with varying dielectric constants to achieve a via impedance target 922. The via impedance target 922 can be a variety of target values such as an average impedance for the via or a specific impedance at a particular location along the via 520. The configuration of the shape and size of the pad 522 within the anti-pad 524 can modify the via impedance 920 along the via 520. The configuration of the anti-pad shape and size can also modify the via impedance 920 and to accommodate multiple dielectric materials in the different layers.

Configuring the via pad and anti-pad design and impedance control through these regions can result in more consistent and desirable impedance characteristics across the hybrid stackup, thus mitigating signal integrity issues.

### 4.0. Functional Overview

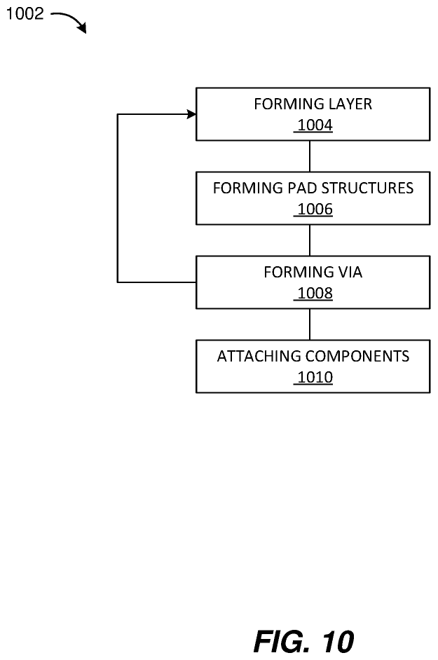

FIG. 10 illustrates an example of a manufacturing process flow 1002 for the electronic system 100 in an embodiment. The manufacturing process flow 1002 can describe the steps and process for manufacturing the mounting substrate 102.

The manufacturing process flow 1002 can include a variety of operations. In an illustrative embodiment, the manufacturing process flow 1002 can include a forming layer step 1004, a forming pad structures step 1006, a forming via step 1008, and an attach components step 1010.

In the forming layer step 1004, the initial portion of the mounting substrate can be formed by forming one of the layers. The layers have at least two portions, a dielectric layer providing mechanical structural stability and a conductive layer in direct contact over the dielectric layer. The conductive layer can be formed from metal or metal alloys including copper, silver, gold, or other similar conductive materials. The dielectric layer can be formed from a variety of materials, such as fiberglass, resin, or other similar materials. The layers of the mounting substrate provide the basis for forming the traces that support the functionality of the electronic system 100.

In the form pad structures layer step 1006, the pad structures can be formed on one of the layers. The pad structures are formed from the conductive layer by removing portions of the conductive layer. The pad structures and other conductive elements on the layer can be formed in a variety of ways including etching, photoetching, drilling, milling, griding, or other similar manufacturing techniques. For example, an etch mask can be placed over the conductive layer and photoetched using ultraviolet light.

The pad structures include a pad formed within an anti-pad opening. The electrical properties of the pad structures are controlled by the physical characteristics of the pad structure including the pad shape, the pad size, the anti-pad shape, and the anti-pad size. The relative size of the pad and the anti-pad can expose different amounts of the dielectric layer. Similarly, the combination of the pad shape and the anti-pad shape can modify the ability of the pad structure to modify impedance.

In some embodiments, the pad can be configured as a non-functional pad. The non-functional pad can be a pad that is not connected to other components on the same layer. The non-functional pad can affect the impedance of the via that passes through it.

In the forming via step 1008, the vias can be formed including the vias connecting the pads of the pad structures. The vias are conductive elements that can connect two or more pads on different layers of the mounting substrate.

The via formation can include a variety of techniques. The via formation can include drilling, laser drilling, etching, or other similar techniques. The via is created by forming the via hole and filling the via hole with a conductive material. The conductive material can form a lining on the walls of the via hole or fill the via hole completely.

In some embodiments, the pads of the pad structures are formed in alignment to allow the interconnection of the pads with the vias.

In other embodiments, the vias can be formed between the top and bottom layers to form a through board via. In yet other embodiments, the vias can be formed between two of the intermediate layers to form buried vias.

In some embodiments, the top and bottom layers can be etched to include mounting pads or other pads for interfacing with electronic components and systems external to the mounting substrate.

After a set of the pad structures and via forming tasks have been performed, the control flow can pass back up to the forming layer step 1004 to add additional layers as needed. If no additional layers are required, the control flow can pass to the attaching components step 1010.

In the attaching component step 1010, the electronic component 305 can be attached to the vias using the mounting pads. The electronic components, such as a ball grid array components, can be attached to the mounting pads on the outer layers. In some embodiments, the electronic components can be attached to both the top layer and the bottom layer of the mounting substrate.

Other examples of these and other embodiments are found throughout this disclosure.

### 5.0. Example Embodiments

Examples of some embodiments are represented, without limitation, in the following clauses and use cases:

According to an embodiment, a method of manufacture of an electronic system comprises forming a first pad structure on a first substrate layer of a mounting substrate, the first pad structure having a first pad located within a first anti-pad opening of a first conductive portion of the first substrate layer, forming a second pad structure on a second substrate layer of the mounting substrate, the second substrate layer over the first substrate layer, the second pad structure having a second pad within a second anti-pad opening of a second conductive portion of the second substrate layer, and the second substrate layer offset from the first substrate layer by a first offset distance, forming a via at least between the first pad and the second pad, the via having a conductive portion for electrically coupling the first pad and the second pad, and the first offset distance configured to reduce the level of via impedance between the first pad and the second pad, and forming a top pad on a top substrate layer over the second substrate layer, the top pad electrically coupled to one of the vias.

In an embodiment, the method wherein forming the first pad structure includes forming the first pad having a circular pad shape and the first anti-pad opening having a rectangular shape with the first pad offset from a closest side of the first anti-pad opening by a pad gap offset distance.

In an embodiment, the method wherein forming the first pad structure includes forming the first pad having a circular pad shape and the first anti-pad opening having a circular shape with the first pad offset from a closest side of the first anti-pad opening by a pad gap offset distance.

In an embodiment, the method wherein forming the first pad structure includes forming the second pad structure having the second anti-pad shape different from the first anti-pad shape.

In an embodiment, the method further comprising forming a second via within the first anti-pad opening.

According to an embodiment, a method of manufacture of an electronic system comprises forming a first pad structure on a first substrate layer of a mounting substrate, the first pad structure having a first pad located within a first anti-pad opening of a first conductive portion of the first substrate layer, forming an intermediate substrate layer over the first substrate layer of the mounting substrate, forming a second pad structure on a second substrate layer of the mounting substrate, the second substrate layer over the first substrate layer and the intermediate substrate layer, the second pad structure having a second pad within a second anti-pad opening of a second conductive portion of the second substrate layer, and the second substrate layer offset from the first substrate layer by a first offset distance, forming a via at least between the first pad and the second pad, the via having a conductive portion for electrically coupling the first pad and the second pad, and the first offset distance configured to reduce the level of via impedance between the first pad and the second pad, forming a top pad on a top substrate layer over the second substrate layer, the top pad electrically coupled to the via, and attaching an electronic component to the top pad.

In an embodiment, the method wherein forming the intermediate substrate layer includes forming the intermediate substrate layer with a non-functional pad directly between the first pad and the second pad.

In an embodiment, the method wherein forming the intermediate substrate layer includes forming the intermediate substrate layer with a third pad structure having a third pad and a third anti-pad opening.

In an embodiment, the method wherein forming the intermediate substrate layer includes forming the intermediate substrate layer with a third pad structure having a third pad and a third anti-pad opening, and the third anti-pad opening having a third anti-pad shape different from the first anti-pad opening.

In an embodiment, the method wherein forming the intermediate substrate layer includes forming the intermediate substrate layer with a third pad structure having a third pad and a third anti-pad opening, and the via electrically coupled to the third pad.

According to an embodiment, an electronic system comprises a mounting substrate having at least a first layer and a second layer, a first pad structure with a first pad within a first anti-pad opening, the first pad structure on the first layer, a second pad structure with a second pad within a second anti-pad opening, the second pad structure on the second layer, and the second layer over the first layer, a via electrically coupled to the first pad and the second pad.

In an embodiment, the system wherein first pad structure includes the first pad having a circular pad shape and the first anti-pad opening having a rectangular shape with the first pad offset from a closest side of the first anti-pad opening by a pad gap offset distance.

In an embodiment, the system wherein the first pad structure includes the first pad having a circular pad shape and the first anti-pad opening having a circular shape with the first pad offset from a closest side of the first anti-pad opening by a pad gap offset distance.

In an embodiment, the system wherein the second pad structure includes the second anti-pad shape different from the first anti-pad shape.

In an embodiment, the system further comprising a second via within the first anti-pad opening.

In an embodiment, the system further comprising an intermediate substrate layer between the first layer and the second layer.

In an embodiment, the system wherein the intermediate substrate layer includes a non-functional pad directly between the first pad and the second pad.

In an embodiment, the system wherein the intermediate substrate layer a third pad structure having a third pad and a third anti-pad opening.

In an embodiment, the system wherein the intermediate substrate layer includes a third pad structure having a third pad and a third anti-pad opening, and the third anti-pad opening having a third anti-pad shape different from the first anti-pad shape.

In an embodiment, the system wherein the intermediate substrate layer includes a third pad structure having a third pad and a third anti-pad opening, and the via electrically coupled to the third pad and the first pad.

### 6.0. Extensions and Alternatives

As used herein, the terms “first,” “second,” “certain,” and “particular” are used as naming conventions to distinguish queries, plans, representations, steps, objects, devices, or other items from each other, so that these items may be referenced after they have been introduced. Unless otherwise specified herein, the use of these terms does not imply an ordering, timing, or any other characteristic of the referenced items.

In the drawings, the various components are depicted as being coupled to various other components by arrows. These arrows illustrate only certain examples of current flows between or through the components. Neither the direction of the arrows nor the lack of arrow lines between certain components should be interpreted as indicating the existence or absence of a flow between the certain components themselves.

In the specification, embodiments of the invention have been described with reference to numerous specific details that may vary from implementation to implementation. Thus, the sole and exclusive indicator of what is the invention and is intended by the applicants to be the invention, is the set of claims that issue from this application, in the specific form in which such claims issue, including any subsequent correction. In this regard, although specific claim dependencies are set out in the claims of this application, it is to be noted that the features of the dependent claims of this application may be combined as appropriate with the features of other dependent claims and with the features of the independent claims of this system, and not merely according to the specific dependencies recited in the set of claims. Moreover, although separate embodiments are discussed herein, any combination of embodiments and/or partial embodiments discussed herein may be combined to form further embodiments.

Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

It is understood that the system functionality can be described using terms like module, unit, system, subsystem, pod, and component that represent devices that can be implemented using different combinations of mechanical and electronic elements. The systems and devices can include electric subsystems, mechanical subsystems, and other physical elements to operate and control the system. These elements can include computing elements that can execute the firmware and software of the system to control mechanical features of the system. In addition, the mechanical elements of the system can operate with or without control mechanisms in regular operation.

What is claimed is:

1. A method of manufacture of an electronic system comprising:
forming a first pad structure on a first substrate layer of a mounting substrate, the first pad structure having a first pad located within a first anti-pad opening of a first conductive portion of the first substrate layer;
forming a second pad structure on a second substrate layer of the mounting substrate, the second substrate layer over the first substrate layer, the second pad structure having a second pad within a second anti-pad opening of a second conductive portion of the second substrate layer, and the second substrate layer offset from the first substrate layer by a first offset distance;
forming a via at least between the first pad and the second pad, the via having a conductive portion for electrically coupling the first pad and the second pad, and the first offset distance configured to reduce the level of via impedance between the first pad and the second pad; and
forming a top pad on a top substrate layer over the second substrate layer, the top pad electrically coupled to the via.

2. The method as claimed in claim 1, wherein forming the first pad structure includes forming the first pad having a circular pad shape and the first anti-pad opening having a rectangular shape with the first pad offset from a closest side of the first anti-pad opening by a pad gap offset distance.

3. The method as claimed in claim 1, wherein forming the first pad structure includes forming the first pad having a circular pad shape and the first anti-pad opening having a circular shape with the first pad offset from a closest side of the first anti-pad opening by a pad gap offset distance.

4. The method as claimed in claim 1, wherein forming the first pad structure includes forming the second pad structure having the second anti-pad shape different from the first anti-pad shape.

5. The method as claimed in claim 1, further comprising forming a second via within the first anti-pad opening.

6. A method of manufacture of an electronic system comprising:
forming a first pad structure on a first substrate layer of a mounting substrate, the first pad structure having a first pad located within a first anti-pad opening of a first conductive portion of the first substrate layer;
forming an intermediate substrate layer over the first substrate layer of the mounting substrate;
forming a second pad structure on a second substrate layer of the mounting substrate, the second substrate layer over the first substrate layer and the intermediate substrate layer, the second pad structure having a second pad within a second anti-pad opening of a second conductive portion of the second substrate layer, and the second substrate layer offset from the first substrate layer by a first offset distance;
forming a via at least between the first pad and the second pad, the via having a conductive portion for electrically coupling the first pad and the second pad, and the first offset distance configured to reduce the level of via impedance between the first pad and the second pad;
forming a top pad on a top substrate layer over the second substrate layer, the top pad electrically coupled to the via; and
attaching an electronic component to the top pad.

7. The method as claimed in claim 6, wherein forming the intermediate substrate layer includes forming the intermediate substrate layer with a non-functional pad directly between the first pad and the second pad.

8. The method as claimed in claim 6, wherein forming the intermediate substrate layer includes forming the intermediate substrate layer with a third pad structure having a third pad and a third anti-pad opening.

9. The method as claimed in claim 6, wherein forming the intermediate substrate layer includes forming the intermediate substrate layer with a third pad structure having a third pad and a third anti-pad opening, and the third anti-pad opening having a third anti-pad shape different from the first anti-pad opening.

10. The method as claimed in claim 6, wherein forming the intermediate substrate layer includes forming the intermediate substrate layer with a third pad structure having a third pad and a third anti-pad opening, and the via electrically coupled to the third pad.

11. An electronic system comprising:
a mounting substrate having at least a first layer and a second layer;
a first pad structure with a first pad within a first anti-pad opening, the first pad structure on the first layer;
a second pad structure with a second pad within a second anti-pad opening, the second pad structure on the second layer, and the second layer over the first layer;
a via electrically coupled to the first pad and the second pad.

12. The system as claimed in claim 11, wherein first pad structure includes the first pad having a circular pad shape and the first anti-pad opening having a rectangular shape with the first pad offset from a closest side of the first anti-pad opening by a pad gap offset distance.

13. The system as claimed in claim 11, wherein the first pad structure includes the first pad having a circular pad shape and the first anti-pad opening having a circular shape with the first pad offset from a closest side of the first anti-pad opening by a pad gap offset distance.

14. The system as claimed in claim 11, wherein the second pad structure includes the second anti-pad shape different from the first anti-pad shape.

15. The system as claimed in claim 11, further comprising a second via within the first anti-pad opening.

16. The system as claimed in claim 11, further comprising an intermediate substrate layer between the first layer and the second layer.

17. The system as claimed in claim 16, wherein the intermediate substrate layer includes a non-functional pad directly between the first pad and the second pad.

18. The system as claimed in claim 16, wherein the intermediate substrate layer a third pad structure having a third pad and a third anti-pad opening.

19. The system as claimed in claim 16, wherein the intermediate substrate layer includes a third pad structure having a third pad and a third anti-pad opening, and the third anti-pad opening having a third anti-pad shape different from the first anti-pad shape.

20. The system as claimed in claim 16, wherein the intermediate substrate layer includes a third pad structure having a third pad and a third anti-pad opening, and the via electrically coupled to the third pad and the first pad.
